(19) United States
(12) Patent Application Publication
(10) Pub. No.: US 2021/0108333 A1
(43) Pub. Date: Apr. 15, 2021

(54) SINGLE CRYSTAL SYNTHETIC DIAMOND MATERIAL VIA CHEMICAL VAPOUR DEPOSITION

(71) Applicant: ELEMENT SIX TECHNOLOGIES LIMITED, DIDCOT, OXFORDSHIRE (GB)

(72) Inventors: MATTHEW LEE MARKHAM, DIDCOT (GB); ANDREW MARK EDMONDS, DIDCOT (GB); HARPREET KAUR DHILLON, DIDCOT (GB); DAVID WILLIAM HARDEMAN, DIDCOT (GB)

(73) Assignee: ELEMENT SIX TECHNOLOGIES LIMITED, DIDCOT, OXFORDSHIRE (GB)

(21) Appl. No.: 16/464,327

(22) PCT Filed: Nov. 30, 2017
(86) PCT No.: PCT/EP2017/080901

§ 371 Date: May 28, 2019

(30) Foreign Application Priority Data
Dec. 1, 2016 (GB) 1620415.8

(51) Int. Cl. C30B 29/04; C30B 29/68; C30B 25/20; C30B 33/12

(52) U.S. Cl. CPC C30B 29/04; C30B 33/12; C30B 25/20; C30B 29/68

(57) ABSTRACT

A single crystal CVD diamond material is disclosed, the material comprising a total nitrogen concentration of at least 3 ppm as measured by secondary ion mass spectrometry (SIMS); and a low optical birefringence such that in a sample of the single crystal CVD diamond material having an area of at least 1.3 mm×1.3 mm, and measured using a pixel size of area in a range 1×1 μm² to 20×20 μm², a maximum value of Δn_{[average]} does not exceed 1.5×10⁻⁴, where Δn_{[average]} is an average value of a difference between refractive index for light polarised parallel to slow and fast axes averaged over the sample thickness. A method of making the material is also disclosed.

### FIELD

The present invention relates to single crystal chemical vapour deposited (CVD) synthetic diamond material and particularly to the synthesis of layers of single crystal CVD synthetic diamond material containing significant quantities of nitrogen dopant.

### BACKGROUND

In the 1980s and 1990s much research was performed by various groups around the world directed to the synthesis of single crystal CVD diamond material. Much of this work disclosed growth of thin layers of single crystal CVD diamond material on single crystal diamond substrates via homoepitaxial growth. While there was a desire to fabricate relatively thick layers of high quality single crystal CVD synthetic diamond material, this proved difficult to achieve in practice. Synthesis of single crystal CVD diamond material requires extreme conditions which need to be generated and then maintained in a stable fashion over extended time periods to successfully grow thick layers of high quality single crystal CVD synthetic diamond material. Furthermore, the nature of the diamond material which is synthesized is sensitive to numerous synthesis parameters forming a complex multi-dimensional synthesis parameter space. Only small areas of this multi-dimensional synthesis parameter space are capable of achieving thick layers of high quality single crystal CVD diamond material. Finding these synthesis regimes, and developing methodologies for generating the correct combination of parameters required to produce and maintain stable growth within one of these synthesis regimes is far from trivial.

In the early 2000s, Element Six Ltd (De Beers Group) filed a series of patent applications directed to the growth of high quality single crystal CVD synthetic diamond materials of a number of different types. These patent applications were based on extensive research over many years developing an understanding of the multi-dimensional synthesis parameter space for single crystal CVD diamond materials and developing methodologies for generating and maintaining the correct combination of parameters required to produce and maintain stable growth within selected synthesis regimes.

Synthesis parameters of importance to single crystal CVD diamond growth were found to include substrate type, substrate processing and growth surface preparation, substrate geometry, substrate temperature and thermal management, microwave power, gas pressure, gas composition and flow rate. The correct combination of these parameters needs to be selected, generated, and maintained in a stable fashion and many of these parameters are interrelated such that if one parameter is changed then others must also be changed in the correct manner in order to remain in a stable growth regime. Some examples of Element Six Ltd patent applications filed in the 2000s are briefly discussed below.

For certain applications it is desirable to minimize the number of defects, or at least certain types of defect, within the diamond lattice structure. For example, for certain electronic applications such as radiation detectors or semi-conductive switching devices it is desirable to minimize the number of charge carriers inherent in the diamond material and increase the mobility of charge carriers intentionally introduced into the material in use. Such a material may be engineered by fabricating a single crystal CVD synthetic diamond material which has a low concentration of impurities which would otherwise introduce charge carriers into the diamond lattice structure. Patent literature relevant to such electronic/detector grade single crystal CVD synthetic diamond material includes WO01/096633 and WO01/096634.

For certain optical applications it is desirable to provide a material which has low optical absorbance and low optical birefringence. Such a material may be engineered by fabricating a single crystal CVD synthetic diamond material which has a low concentration of impurities, which would otherwise increase the optical absorbance of the material, and a low concentration of extended defects which would otherwise introduce anisotropic strain into the diamond lattice structure causing birefringence. Patent literature relevant to such optical grade single crystal CVD synthetic diamond material includes WO2004/046427 and WO2007/066215.

In contrast to the low defect materials described above, for certain applications it is desirable to intentionally introduce a significant but controlled quantity, type, and distribution of defects into the diamond lattice structure. For example, introducing boron into the diamond lattice by providing a boron containing gas within the CVD process gases provides an acceptor level within the band structure of the diamond material thus forming a p-type semi-conductor. If extremely high levels of boron are introduced into the diamond lattice structure the material shows metal-like conductivity. Such materials are useful as electrodes, as electrochemical sensing electrodes, and in electronic applications. Patent literature relevant to such boron doped single crystal CVD synthetic diamond material includes WO03/052174.

Another example is that of nitrogen doped single crystal CVD synthetic diamond materials. Nitrogen is one of the most important dopants in CVD diamond material synthesis as it has been found that providing nitrogen in the CVD process gas increases the growth rate of the material and can also affect the formation of crystallographic defects such as dislocations. As such, nitrogen doping of single crystal CVD synthetic diamond materials has been extensively investigated and reported in the literature. Nitrogen doped CVD synthetic diamond material tends to be brown in colour. As such, for the previously discussed applications, such as optical applications, it has been found to be advantageous to develop techniques which intentionally exclude nitrogen from the CVD process gases. However, for applications such as mechanical applications where optical, electronic, and quantum coupling parameters are not a concern, nitrogen doping to significant levels can be useful in achieving growth of thick layers of CVD synthetic diamond material. Patent literature relevant to such nitrogen doped single crystal CVD synthetic diamond material includes WO2003/052177.

For certain applications, it has also been found to be advantageous to utilize a synthesis methodology which involves introducing two or more dopants into the CVD synthesis process. For example, as described previously, nitrogen doped CVD synthetic diamond material tends to be brown in colour. However, it has been found that if a co-dopant such as boron or silicon is introduced into the synthesis process in combination with nitrogen then it is possible to fabricate colourless or near colourless single crystal CVD diamond material at nitrogen levels which would otherwise result in a brown colouration. Patent literature relevant to such co-doped single crystal CVD synthetic diamond material includes WO2006/136929.

Co-doping can also be used as a means of intentionally introducing one or more layers of distinctive doped material into a single crystal CVD diamond as a way of identifying the material as synthetic without detrimentally affecting the visual quality of the material. For example, a colourless or near colourless single crystal CVD diamond can be manufactured which has one or more layers of co-doped material which are not visible under normal viewing conditions but which are visible under fluorescent conditions. Such an approach is described in WO2005/061400.

Finally, EP2985368 (Sumitomo) suggests incorporating a range of different types of defects into single crystal CVD diamond material for mechanical tool applications in order to suppress chipping. To achieve this mechanical tool component a grooved substrate, ion implantation, and relatively high levels of methane and nitrogen were utilized to create a range of defects within the product material. Single crystal CVD diamond product of varying lateral dimensions was achieved but at relatively low thicknesses of 0.7 mm.

In light of the above, it will be evident that single crystal CVD diamond materials come in a range of different forms and can be engineered to have a range of different properties for particular applications.

### SUMMARY OF INVENTION

One of the most important synthesis regimes for commercial applications is that described in WO2004/046427. As described in the background section of the present specification, WO2004/046427 is directed to the fabrication of single crystal CVD diamond material with low optical absorbance and low optical birefringence. While such a material has found to be required for certain optical applications, the synthesis regime as described therein has also been found to be useful for applications which do not necessarily require all the advantageous optical qualities of the product material. For example, even for applications which do not require low optical birefringence, it has been found that the synthesis methodology as described in WO2004/046427 can be advantageous for commercial production as it allows high quality, thick, single crystal CVD diamond to be consistently manufactured which relatively good growth rates and with relatively high yields compared to other processes.

Embodiments of WO2004/046427 are described as producing a layer of single crystal CVD diamond having substantially no regions of high birefringence and containing single substitutional nitrogen in a concentration range 3×10¹⁵ atoms/cm³ to 5×10¹⁷ atoms/cm³ as measured by electron paramagnetic resonance spectroscopy (EPR). Such materials having low and controlled levels of nitrogen and low strain are described as being manufactured using a chemical vapour deposition technique in which low and controlled levels of gas phase nitrogen are introduced into the synthesis atmosphere within a concentration range 300 ppb to 5 ppm. The present inventors have realized that for certain applications it would be desirable to fabricate low strain single crystal CVD diamond material with higher nitrogen concentrations than those described in the embodiments of WO2004/046427. However, increasing the levels of nitrogen in the synthesis atmosphere to increase the concentration of nitrogen in the single crystal CVD diamond product material has been found to increase strain and birefringence in the product material. Furthermore, the increased strain can also lead to increases in cracking during synthesis or post-synthesis processing, thus reducing yield.

The aforementioned problem has been solved by growing a thin layer of lower nitrogen single crystal CVD diamond material over the substrate and then moving into a high nitrogen growth process for the high nitrogen single crystal CVD diamond product material. While not being bound by theory, it is believed that high nitrogen single crystal CVD diamond material overgrows pits in the substrate (e.g. formed by a plasma etch to remove substrate damage) without properly filling in the pits resulting in strain/dislocation formation. A lower nitrogen, lower growth rate initial layer fills in these pits prior to moving to a higher nitrogen, high growth rate synthesis. In this way, it is possible to fabricate a high nitrogen concentration single crystal CVD diamond product material which also has low strain. Of course, one alternative method for avoiding the problem of pitting in the substrate formed during etching of the substrate prior to growth is to reduce or avoid the use of a substrate etch which forms the pits. However, the substrate etching process is designed to remove surface and subsurface substrate damage as a result of mechanical processing. If this substrate damage is not removed by etching then it also causes dislocation formation and strain. The present solution thus retains a substrate etching step to remove mechanical processing damage from the substrate growth surface but then uses a low nitrogen, low growth rate synthesis process to fill pits and irregularities in the substrate surface after the etch and prior to moving to a higher nitrogen, higher growth rate synthesis process. In this manner, it is possible to achieve a single crystal CVD diamond product which has both a high nitrogen content and also a low birefringence.

According to a first aspect of the present invention there is provided a single crystal CVD diamond material comprising:
a total nitrogen concentration of at least 3 ppm as measured by secondary ion mass spectrometry (SIMS); and
a low optical birefringence such that in a sample of the single crystal CVD diamond material having an area of at least 1.3 mm×1.3 mm, and measured using a pixel size of area in a range 1×1 μm² to 20×20 μm², a maximum value of Δn_{[average]} does not exceed 1.5×10⁻⁴, where Δn_{[average]} is an average value of a difference between refractive index for light polarised parallel to slow and fast axes averaged over the sample thickness.

According to a second aspect of the present invention there is provided a method of fabricating a single crystal CVD diamond material according to the first aspect of the invention, the method comprising:
preparing a plurality of single crystal diamond substrates by mechanically processing the substrates and then etching the substrates to remove mechanical processing damage,
wherein a growth surface of each substrate has a density of defects such that surface etch features related to defects formed by a revealing plasma etch is below 5×10³/mm²;
growing a first layer of single crystal CVD diamond material on the growth surface of each single crystal diamond substrate, and
growing a second layer of single crystal CVD diamond material on the first layer of single crystal CVD diamond material,
wherein the second layer of single crystal CVD diamond material is grown under higher nitrogen conditions than the first layer of single crystal CVD diamond material, synthesis conditions being controlled in order to achieve the single crystal CVD diamond material of the first aspect of the invention.

The single crystal CVD diamond product material has a high nitrogen content and a low strain and can be fabricated in thick layers. Synthesis conditions can be controlled in order to form yellow coloured material in as grown form or after annealing treatment to remove brown colouration. The as-grown product material can be irradiated to produce blue coloured material. Alternatively, the as-grown material can be irradiated and annealed to produce pink coloured material. Such materials can be fabricated into cut gemstones for jewelry applications. Alternatively, such materials can be used in quantum sensing and information processing applications where strain reduction can result in more stable nitrogen-vacancy defects and increased sensitivity. Alternatively still, such materials can be used in mechanical applications. In all cases, lower strain can result in higher synthesis yields and also improved surface processing quality and yield.

### BRIEF DESCRIPTION OF THE DRAWINGS

For a better understanding of the present invention and to show how the same may be carried into effect, embodiments of the present invention will now be described by way of example only with reference to the accompanying drawings, in which:

FIG. 1 illustrates the basic steps involved in fabricating a single crystal CVD diamond material according to the present invention.

### DETAILED DESCRIPTION

As described in the summary of invention section of this specification, the key to achieving the present invention is to provide a methodology which achieves a single crystal CVD diamond product material with both high nitrogen content and also low strain and birefringence.

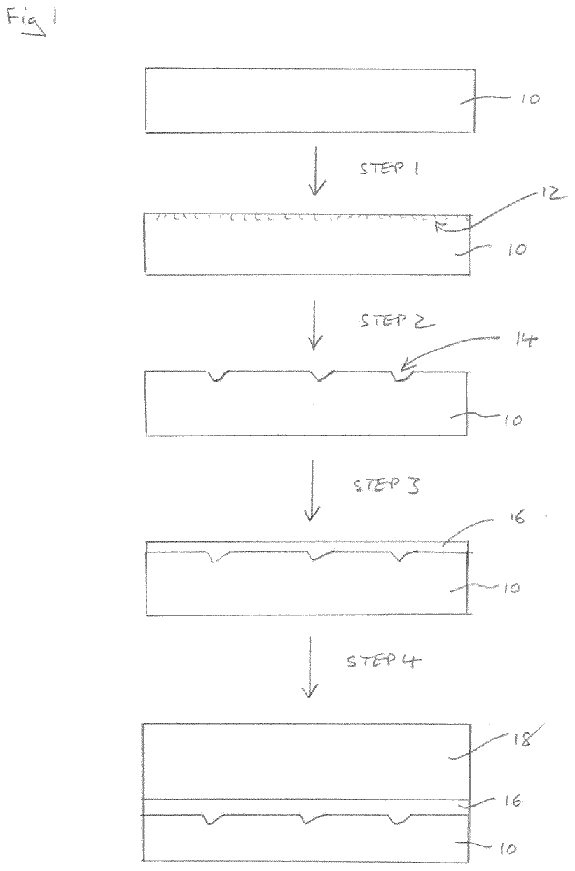

The basic methodology is illustrated in FIG. 1. In step 1, a substrate 10 is mechanically processed to a desired geometry and surface finish. Mechanical processing comprises lapping to a desired thickness and then polishing to a desired surface roughness and flatness. Such mechanical processing produces surface and sub-surface damage 12 to the growth surface of the substrate 10. This surface and sub-surface damage 12 can nucleate dislocations and generate strain in single crystal CVD diamond material grown on such a surface. Accordingly, in step 2 an etch process is applied to the growth surface 10 of the substrate to remove this damage. While this etch process removes surface and sub-surface damage, it also causes pits 14 to form in the growth surface of the substrate 10, particularly where defects such as dislocations are located in the substrate 10. Such pits 14 are not usually problematic for single crystal CVD diamond material grown on such a surface using a synthesis atmosphere with a low and controlled nitrogen concentration as the single crystal CVD diamond material tends to fill in the pits without nucleating dislocations and generating strain. However, when a high nitrogen, fast growth rate synthesis process is utilized the single crystal CVD diamond material tends to over-grow pits in the substrate without filling leading to a discontinuity in the diamond lattice generating dislocations and strain. To solve this problem, in step 3 a thin layer 16 of single crystal CVD diamond material is grown using a low and controlled nitrogen concentration to fill in pits 14 on the substrate 10 before moving into a higher nitrogen growth process in step 4 yielding high nitrogen, low strain diamond material 18.

In general, methods according to the present invention comprise the following steps:
preparing a plurality of single crystal diamond substrates by mechanically processing the substrates and then etching the substrates to remove mechanical processing damage, wherein a growth surface of each substrate has a density of defects such that surface etch features related to defects formed by a revealing plasma etch is below 5×10³/mm²;
growing a first layer of single crystal CVD diamond material on the growth surface of each single crystal diamond substrate, and
growing a second layer of single crystal CVD diamond material on the first layer of single crystal CVD diamond material,
wherein the second layer of single crystal CVD diamond material is grown under higher nitrogen conditions than the first layer of single crystal CVD diamond material.

The first layer of single crystal CVD diamond material can be grown under a synthesis atmosphere containing less than 5 ppm, 3 ppm, 1 ppm, or 0.8 ppm of nitrogen. According to certain embodiments the thin layer of single crystal CVD diamond material 16 may be fabricated using a high purity synthesis process (e.g. according to WO2001/096633) or a synthesis process which uses low and controlled nitrogen addition (e.g. according to WO2004/046427).

The second layer of single crystal CVD diamond material is grown with a synthesis atmosphere containing more than 5 ppm, 7 ppm 10 mm, 15 ppm, 20 ppm, or 30 ppm of nitrogen, optionally no more than 300 ppm. The first layer can be grown to a thickness of at least 5 micrometres and/or no more than 200 micrometres. The first layer should be grown under conditions to ensure that defects in the substrate are filled in while retaining good continuity of the crystal lattice.

After growth the original substrate 10 and the thin layer of low nitrogen single crystal CVD diamond material 16 can be removed (e.g. via laser cutting, electron beam, or some other method) to yield a free-standing single crystal CVD diamond product of high nitrogen, low strain material 18. The single crystal CVD diamond material comprises: a total nitrogen concentration of at least 3 ppm as measured by secondary ion mass spectrometry (SIMS); and a low optical birefringence such that in a sample of the single crystal CVD diamond material having an area of at least 1.3 mm×1.3 mm, and measured using a pixel size of area in a range 1×1 μm² to 20×20 μm², a maximum value of Δn_{[average]} does not exceed 1.5×10⁻⁴, where Δn_{[average]} is an average value of a difference between refractive index for light polarised parallel to slow and fast axes averaged over the sample thickness. Certain embodiments can have a maximum value of Δn_{[average]} that does not exceed 8×10⁻⁵ or even 5×10⁻⁵ or lower. Nominally a lower limit for the maximum value of Δn_{[average]} may be 1×10⁻⁷. The single crystal CVD diamond material fabricated using the methodology describe herein may have a thickness of at least 0.1 mm, 0.2 mm, 0.3 mm, 0.4 mm, 0.5 mm, 0.7 mm, 1.0 mm, 1.5 mm, 2.0 mm, 2.5 mm, 3.0 mm, or 5 mm and optionally no more than 20 mm. For the thicker embodiments in excess of 1 mm thickness, a sample of such a material have a thickness in a range 0.5 mm to 1.0 mm may be extracted and used to measure the birefringence characteristics.

The optical birefringence can be measured in a direction of highest birefringence to within ±10° which will generally correspond to the growth direction of the single crystal CVD diamond material as dislocations tend to propagate through the material in the growth direction.

The single crystal CVD diamond material may have a total nitrogen concentration of at least 5 ppm, 7 ppm 10 mm, 15 ppm, 20 ppm, or 30 ppm as measured by secondary ion mass spectrometry (SIMS) and optionally no more than 50 ppm. The single crystal CVD diamond material may have a neutral single substitutional nitrogen (Nₛ⁰) concentration greater than 5×10¹⁷ atoms/cm³, 8×10¹⁷ atoms/cm³, or 1×10¹⁸ atoms/cm³ as measured by electron paramagnetic resonance and optionally no more than 1×10²⁰ atoms/cm³.

The as-grown product material can be coloured brown similar to that described in WO2003/052177. Alternatively, the as-grown product material can be coloured yellow, e.g. similar to that described in WO2011/076643. The as-grown material can be treated after synthesis by applying annealing treatments as described in WO2004/022821. Blue coloured material can be fabricated via irradiation in a similar manner to that described in WO2010/149779. Pink coloured material can be fabricated via irradiation and annealing in a similar manner to that described in WO2010/149775. Such coloured products can be similar in colour to those described in the prior art but with lower strain more comparable with the colourless or near colourless product material of WO2004/046427.

The single crystal CVD diamond material according to the present invention may be used in a range of applications including optical applications, thermal applications, jewelry applications in the form of a cut gemstone, quantum sensing and information processing applications, and as substrates for further CVD diamond growth (e.g. via vertical slicing to form substrates with low defect growth surfaces).

While this invention has been particularly shown and described with reference to embodiments, it will be understood to those skilled in the art that various changes in form and detail may be made without departing from the scope of the invention as defined by the appending claims.

1. A single crystal CVD diamond material comprising:
a total nitrogen concentration of at least 3 ppm as measured by secondary ion mass spectrometry (SIMS); and
a low optical birefringence such that in a sample of the single crystal CVD diamond material having an area of at least 1.3 mm×1.3 mm, and measured using a pixel size of area in a range 1×1 μm² to 20×20 μm², a maximum value of Δn_{[average]} does not exceed 1.5×10⁻⁴, where Δn_{[average]} is an average value of a difference between refractive index for light polarised parallel to slow and fast axes averaged over the sample thickness.

2. A single crystal CVD diamond material according to claim 1,
wherein the single crystal CVD diamond material has a thickness of at least 0.1 mm, 0.2 mm, 0.3 mm, 0.4 mm, 0.5 mm, 0.7 mm, 1.0 mm, 1.5 mm, 2.0 mm, 2.5 mm, 3.0 mm, or 5 mm.

3. A single crystal CVD diamond material according to claim 1,
wherein the sample of single crystal CVD diamond material used to measure birefringence has a thickness in a range 0.5 mm to 1.0 mm.

4. A single crystal CVD diamond material according to claim 1,
wherein the total nitrogen concentration of the single crystal CVD diamond material is at least 5 ppm, 7 ppm 10 mm, 15 ppm, 20 ppm, or 30 ppm.

5. A single crystal CVD diamond material according to claim 1,
wherein the maximum value of Δn_{[average]} does not exceed 8×10⁻⁵.

6. A single crystal CVD diamond material according to claim 1,
wherein the maximum value of Δn_{[average]} does not exceed 5×10⁻⁵.

7. A single crystal CVD diamond material according to claim 1,
wherein the optical birefringence is measured in a direction of highest birefringence to within ±10°.

8. A single crystal CVD diamond material according to claim 1,
wherein the single crystal CVD diamond material has a neutral single substitutional nitrogen (Nₛ⁰) concentration greater than 5×10¹⁷ atoms/cm³, 8×10¹⁷ atoms/cm³, or 1×10¹⁸ atoms/cm³ as measured by electron paramagnetic resonance.

9. A single crystal CVD diamond material according to claim 1,
wherein the single crystal CVD diamond material is coloured brown, yellow, blue, or pink.

10. A single crystal CVD diamond material according to claim 1,
wherein the single crystal CVD diamond material is in the form of a cut gemstone.

11. A method of fabricating a single crystal CVD diamond material according to claim 1, the method comprising:
preparing a plurality of single crystal diamond substrates by mechanically processing the substrates and then etching the substrates to remove mechanical processing damage, wherein a growth surface of each substrate has a density of defects such that surface etch features related to defects formed by a revealing plasma etch is below 5×10³/mm²;
growing a first layer of single crystal CVD diamond material on the growth surface of each single crystal diamond substrate, and
growing a second layer of single crystal CVD diamond material on the first layer of single crystal CVD diamond material,
wherein the second layer of single crystal CVD diamond material is grown under higher nitrogen conditions than the first layer of single crystal CVD diamond material.

12. A method according to claim 11,
wherein the first layer of single crystal CVD diamond material is grown with a synthesis atmosphere containing less than 5 ppm, 3 ppm, 1 ppm, or 0.8 ppm of nitrogen.

13. A method according to claim 11,
wherein the second layer of single crystal CVD diamond material is grown with a synthesis atmosphere containing more than 5 ppm, 7 ppm 10 mm, 15 ppm, 20 ppm, or 30 ppm of nitrogen.

14. A method according to claim 11,
wherein the first layer is grown to a thickness of at least 5 micrometres.

15. A method according to claim 11,
wherein the first layer is grown to a thickness of no more than 200 micrometres.

16. A method according to claim 11,
wherein the second layer of single crystal CVD diamond material is yellow or brown.

17. A method according to claim 11,
wherein the second layer of single crystal CVD diamond material is irradiated to produce a blue coloured material.

18. A method according to claim 11,
wherein the second layer of single crystal CVD diamond material is irradiated and annealed to produce a pink coloured material.
